(19) United States
(12) Patent Application Publication
(10) Pub. No.: US 2021/0239737 A1
(43) Pub. Date: Aug. 5, 2021

(54) ANNOTATED DECODE OF OSCILLOSCOPE SIGNALS

(71) Applicant: Microsoft Technology Licensing, LLC, Redmond, WA (US)

(72) Inventors: Adam Nelson Swett, Seattle, WA (US); Robert James Ray, Snoqualmie, WA (US); Benjamin Schanz, Seattle, WA (US)

(21) Appl. No.: 16/779,279

(22) Filed: Jan. 31, 2020

(51) Int. Cl. G01R 13/02; G06K 9/00

(52) U.S. Cl. CPC G01R 13/02; G06K 9/00671

(57) ABSTRACT

Signal analysis arrangements and techniques for electrical signals monitored by oscilloscope devices are discussed herein. In one example, a method includes obtaining one or more digital images that capture an oscilloscope user interface presenting a trace of a signal monitored by the oscilloscope, and processing at least the trace in the one or more digital images to decode a connotation of the signal. Based at least on the connotation, the method includes generating an annotation overlay indicating one or more characteristics of the signal.

### BACKGROUND

Various testing and monitoring equipment can be employed to verify and debug electrical circuit designs. This equipment includes oscilloscopes, signal analyzers, spectrum analyzers, bus analyzers, logic analyzers, among other equipment. Typically, these pieces of equipment comprise discrete devices with signal probes, internal signal conditioning and digitization circuitry, and viewscreens. Over the years, this equipment has become more sophisticated in what information can be monitored and presented to operators. As circuitry under test has changed, so has the equipment to test, debug, and monitor such circuitry.

However, oscilloscope devices largely maintain a straightforward operation having input probes that couple to circuitry under test and a viewscreen which shows a live representation of a monitored electrical signal or waveform detected by the input probes. Various viewing options are typically available to an oscilloscope operator for control of how the waveforms are presented on the built-in viewscreen, such as amplitude (vertical) adjustment, time scale/base (horizontal) adjustment, signal marking or coloring, and various triggering options, among other options. Although oscilloscopes can display live signal waveforms, many still are limited in the amount of signal interpretation that can be performed. As many signals that are monitored comprise digital signals, a mere waveform representation might not be able to provide an operator of an oscilloscope with the desired information for proper signal analysis.

### OVERVIEW

Signal analysis arrangements and techniques for electrical signals monitored by oscilloscope devices are discussed herein. In one example, a method includes obtaining one or more digital images that capture an oscilloscope user interface presenting a trace of a signal monitored by the oscilloscope, and processing at least the trace in the one or more digital images to decode a connotation of the signal. Based at least on the connotation, the method includes generating an annotation overlay indicating one or more characteristics of the signal.

This Overview is provided to introduce a selection of concepts in a simplified form that are further described below in the Detailed Description. It may be understood that this Overview is not intended to identify key features or essential features of the claimed subject matter, nor is it intended to be used to limit the scope of the claimed subject matter.

### BRIEF DESCRIPTION OF THE DRAWINGS

Many aspects of the disclosure can be better understood with reference to the following drawings. While several implementations are described in connection with these drawings, the disclosure is not limited to the implementations disclosed herein. On the contrary, the intent is to cover all alternatives, modifications, and equivalents.

FIG. 1 illustrates a signal analysis system in an implementation.

FIG. 2 illustrates operations of a signal analysis system in an implementation.

FIG. 3 illustrates a signal analysis system in an implementation.

FIG. 4 illustrates a computing system configured to implement at least a portion of a signal analysis system in an implementation.

FIG. 5 illustrates an example annotation overlay in an implementation.

FIG. 6 illustrates an example annotation overlay in an implementation.

FIG. 7 illustrates an example annotation overlay in an implementation.

### DETAILED DESCRIPTION

The examples herein describe several enhanced techniques for signal analysis and computer-aided debug of electrical circuits. Typically, oscilloscopes and other similar test equipment are employed to probe various signaling or components of electrical circuits. This test equipment can display to a user or operator a waveform of signals currently being probed with one or more external probe elements coupled to the circuit. However, oscilloscopes provide a real-time or live view of monitored signals, which can lead to difficulty in determining signal behavior over time or decoding actual data carried by the signals. Moreover, signal glitches or errors might be missed by monitoring rapidly changing signals on an oscilloscope screen, complicating debug or leading to slow and manual step-throughs of signal sequences. In the examples herein, a user can employ a user device to capture images or video of an oscilloscope display, and those images or video can be processed to produce graphical annotations indicating intelligent interpretation of the signals. Moreover, video segments can be replayed with various signal properties or signal connotations overlaid thereon, allowing users to review sequences of operation of a test circuit more effectively and at a selected speed. The captured video or images can be shared over communication links with one or more other users, providing for collaborative viewing and debug of circuits. Advantageously, a manufacturing worker might encounter a malfunctioning circuit and capture a video of an oscilloscope waveform using a smartphone or augmented reality (AR) device. This captured video can be provided to technical support personnel in a local or remote location. The technical support personnel can troubleshoot operations of the affected circuit using the captured video which has been processed to determine signal properties, decoded data carried by the signal, signal timing properties, or other information. Collaboration among teams spread over various geographic regions can be established by analyzing video or images captured of oscilloscope screens or other monitoring equipment which is local to the circuitry under test. More efficient resolution of circuit problems and design iterations can thus be provided by the examples herein.

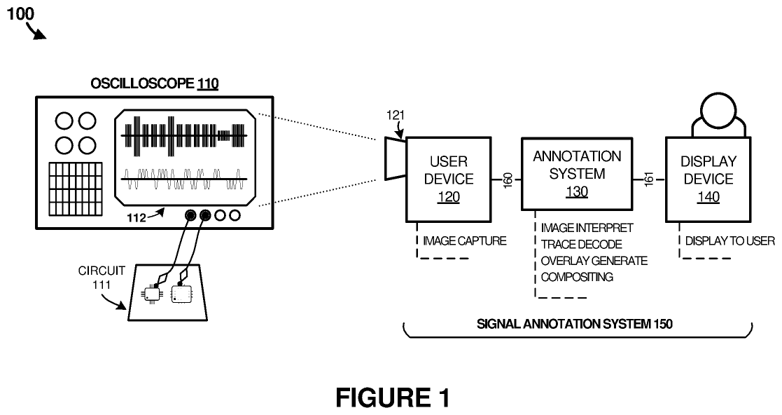

FIG. 1 illustrates signal analysis system 100 in an implementation. System 100 includes oscilloscope 110, user device 120, annotation system 130, and display device 140. User device 120 and annotation system 130 communicate over link 160. Annotation system 130 and display device 140 communicate over link 161. Oscilloscope 110 is shown coupled to a test circuit 111, which is exemplary of any circuit or system which can be monitored by oscilloscope 110. Although two ‘probes’ and example circuitry are shown in FIG. 1, it should be understood that any suitable monitoring or signal gathering arrangement might be employed by oscilloscope 110.

In operation, oscilloscope 110 can monitor various signals produced by circuitry 111 and display such signals on display screen 112. In FIG. 1, two example signals are shown, which are referred to as signal traces or traces herein. A first signal trace (upper) might reflect one monitored signal or circuit, and a second signal trace (lower) might reflect another monitored signal or circuit. The signals might be related or unrelated, and one might be a data stream while the other is a clock signal for that data stream. Other configurations are possible, including data streams which include embedded or encoded data/clock representation. However, the traces shown on display screen 112 merely show waveforms having a vertical amplitude which vary over a horizontal timescale.

During display of the traces by display screen 112, user device 120 can capture one or more images of display screen 112. These one or more images can be processed by annotation system 130 to interpret the images to detect traces indicated therein. These traces can be interpreted by annotation system 130 to decode digital information carried by signals indicated in the traces. The digital information might comprise digital bits, digital words, clock rates, transaction types, packet types, frame boundaries, frame ordering, or other information. From here, annotations comprising textual or graphical overlays can be generated which represent at least a portion of the information interpreted from the traces. These annotations, in conjunction with the captured images, can be displayed to a user on a display screen, such as on display device 140.

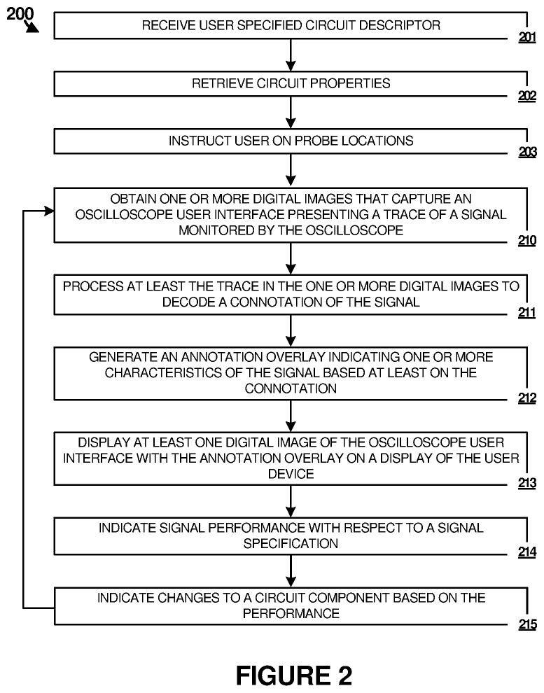

FIG. 2 illustrates operations of signal analysis system 100 in an implementation. Although the operations of FIG. 2 are discussed in the context of certain elements of FIG. 1, it should be understood that a different arrangement of elements might perform similar operations. In FIG. 2, operations 201-203 can be optionally performed prior to operations 210-213. In some examples, operations 201-203 may be omitted.

In operation 201, annotation system 130 receives a user-specified circuit descriptor or identifier. This circuit descriptor or identifier can specify a circuit under test or target circuit for which an operator of an oscilloscope desires to monitor. The circuit descriptor might comprise a device or circuit model number, circuit board revision indicator, circuit schematic indictor, product descriptor, serial number, or other descriptors. In addition to the circuit descriptor, a user can provide an indication or identifier of selected signals associated with target circuit 111, such as link identifiers, bus identifiers, or other indications which relate to a portion of target circuit 111 that the user desires to monitor. For example, a user might want to monitor a management bus, memory bus, or peripheral bus for a particular circuit board. The user might indicate to annotation system 130 a circuit board identifier along with selected signals (e.g. an Inter-Integrated Circuit or I2C bus), which might be one bus among many signal type and signal instance options presented by a user interface to annotation system 130.

Annotation system 130 can process the identifiers, such as the circuit descriptor and signals identifiers, to retrieve (202) corresponding physical properties of target circuit 111 from a circuit representation stored in a storage system. This circuit representation might comprise physical grid locations of various electrical nodes in a circuit layout along with associated signal routes, pads, or components which are included in a database or suitable data structure. Physical properties of target circuit 111 can include electrical nodes, probe points, schematic information, layout information, manufacturing information, and the like, for target circuit 111. Based on this information, annotation system 130 can determine physical locations on target circuit 111 for placement of probes of oscilloscope 111 to monitor the indicated signals. Annotation system 130 can then instruct (203) the user on the probe locations for positioning oscilloscope probes to properly monitor the selected signals on target circuit 111. Annotation system 130 might present graphical indications to the user that indicate oscilloscope probe points in relation to components of target circuit 111. In such examples, these graphical indications can be presented on a graphical user interface of a user device, which might include a smartphone, tablet, or computer, and the graphical user interface might overlay the graphical indications of probe points onto a picture or graphical representation of target circuit 111.

In other examples, augmented reality (AR) display configurations can be employed. In AR examples, the user might position a camera or imaging sensor towards a scene that includes target circuit 111, and a graphical display of target circuit 111 can have graphical indications of probe points overlaid or composited with the ‘live’ scene in the AR display. In yet further examples, the circuit descriptors might be automatically detected responsive to a user positioning one or more portions of target circuit 111 within the view of imaging device 121 of a user device 120. User device 120 or annotation system 130 can perform image text recognition on these one or more portions of target circuit 111, such as recognition of serial numbers, model numbers, circuit identifiers, bar codes, QR codes, and the like. Alternatively, image object recognition might be performed to detect target circuit 111 based on graphical processing on one or more images taken of target circuit 111, such as by annotation system 130 recognizing an arrangement or layout of the circuit board and associated on-board components. Image processing can be performed by portions of annotation system 130 in conjunction with portions of user device 120 and display device 140 which might include imaging sensors, display screens, data processing elements, and user interface equipment.

Continuing the description of the operations in FIG. 2, once oscilloscope probes have been applied to target circuit 111, annotation system 130 obtains (210) one or more digital images that capture an oscilloscope user interface presenting a trace of a signal monitored by the oscilloscope. Oscilloscope 110 can monitor various signals produced by circuitry 111 and display such signals on display screen 112. In FIG. 1, two example signals are shown.

To obtain the one or more digital images, annotation system 130 might employ a device or system to capture an image of display screen 112 of oscilloscope 110. For example, user device 120 with imaging device 121 might be employed to capture images of display screen 112 of oscilloscope 110. These images might comprise individual images or multiple images collected into a video or other format. These images can be provided over link 160 to annotation system 130. Control instructions or image capture commands can be issued by annotation system 130 over link 160 or by a user in control of user device 120 via a user interface, such as a touch screen or other user interface device. Alternatively, one or more digital images might be captured by another device or another user and transferred to annotation system 130 over one or more network links. These images might have been captured in the past or at times not congruent with further operations of annotation system 130, which might include archival images or previously captured and stored images. Furthermore, oscilloscope 110 might include an image capture system which can capture one or more “screen shots” or provide rendered graphics data as an image file to annotation system 130.

These digital images can comprise any digital image format or digital video format included in one or more data files, such as JPG (Joint Photographic Experts Group), GIF (Graphics Interchange Format), PNG (Portable Network Graphics), TIFF (Tagged Image File Format), MP4 (Moving Pictures Expert Group 4), AVI (Audio Video Interleave), FLV (Flash Video Format), WMV (Windows Media Video), MOV (Apple QuickTime Movie), WebM (.webm), Ogg Video (.ogv), among others.

Responsive to the one or more digital images being obtained by annotation system 130, annotation system 130 processes (211) at least a trace in the one or more digital images to decode a connotation of the signal. Annotation system 130 performs various image processing to detect one or more traces contained in the image data, which might include waveform detection, machine learning, or pattern matching processes. These traces describe one or more signals captured by oscilloscope 110. The visual representation exhibited by the traces can comprise various timescale and amplitude properties, which might correspond to a “zoom” level or other on-screen configuration. Once traces have been detected in the one or more images, then annotation system 130 can process the individual traces to detect one or more characteristics of the traces which comprise connotations of the underlying signals. These characteristics can include decoded digital information carried by the signals, such as digital codewords, data bits encoded in the signals, data words, clock rates, transaction types, packet types, frame boundaries, frame ordering, or other information.

In addition to processing the image data alone to detect and determine connotations of underlying signals, annotation system 130 can consider additional information when processing the traces. This additional information might be user-provided attributes associated with the signal monitored by the oscilloscope or historical data gathered from past image/signal interpretation. The additional information can include indications on protocol type associated with the signal, a signal amplitude property, and a signal time scale property, or other attributes which can inform a signal interpretation process and assist annotation system 130 in decoding digital information carried by the traces. The user-provided attributes might be received over a user interface portion of annotation system 130 or user device 120, or might be retrieved from stored text files, attributes files, markup, or other user-provided data. The historical attributes can be related to past decoded connotations, stored in a data storage system, and similarity obtained as the user-provided information.

From here, annotation system 130 generates (212) one or more annotation overlays indicating one or more characteristics of the signals based at least on the decoded connotations. These annotations comprise textual or graphical overlays can be generated which represent at least a portion of the information interpreted from the traces. For example, if a digital codeword or data bits were decoded from the image data and associated traces, then representations of the digital codewords can be included in the annotations in a graphical or textual overlay positioned on or near corresponding portions of the traces. When packet types or transaction types are detected, indications of the types (such as a read or write transaction) can be positioned on or near corresponding portions of the traces. Other information might be included in the overlays, including timescales, amplitudes, clock frequencies, and the like.

In one example, an I2C (Inter-Integrated Circuit) or System Management Bus (SMBus) signals are monitored by oscilloscope 110, which is carried by monitored links of circuit 111. These links might comprise a Serial Data Line (SDA) and a Serial Clock Line (SCL). The SDA line of circuit 111 can be monitored by a circuit probe of oscilloscope 110 and the corresponding signal displayed onto display screen 112. However, the SDA line carries digital signals encoded into a physical representation comprised of ‘1’, ‘0’, START, and STOP signal levels or signal configurations. It can be difficult for a user of oscilloscope 110 to determine data presently displayed by oscilloscope 110, especially when the signal changes over time. To aid a user in decoding the signal, annotation system 130 can obtain an image captured of display screen 112, process the image data to determine traces indicated in the image data, and interpret the traces to detect a communication protocol carried by the underlying signal, and decode the data according to the communication protocol. Thus, I2C or SMBus signals can be annotated to a user for intelligent interpretation of raw signal traces captured by an oscilloscope or similar device.

These overlays, in conjunction with the captured images, can be displayed to a user on a display screen. In FIG. 1, display device 140 displays (213) at least one digital image of the oscilloscope user interface, such as the image or video originally captured of display screen 112, with the overlays indicating the annotations which are composited with the captured image on a display of the user device. When video is captured, then the overlays might be dynamic and change with the current traces shown by the video. Also, when users capture the image data or video data, the pixels showing display screen 112 might be off-center or change over time due to natural movement of the user device or user. Annotation system 130 can detect this movement or change in spatial arrangement of display screen 112 within the one or more images and ensure that the overlays are properly positioned over relevant trace portions.

A user might operate user device 120 to capture an operational sequence of target circuit 111 shown on display screen 112 of oscilloscope 110, such as for a selected bus or set of signals. User device 120 can capture a video over a selected timeframe, such as from power-on of target circuit 111 until a selected endpoint to capture a startup sequence. From here, the video data can be transferred to annotation system 130 which can process the video data to identify connotations of the signals, such as codewords, data bits, and bus data, as well as various signal characteristics including signal timing performance. This signal timing performance might indicate when signal timings meet, fail, or are marginal with respect to signal specifications, such as protocol-based timing parameters or requirements associated with the monitored signals. Annotation system 130 can then generate overlays or annotations for the video data which indicate (214) properties of the signals and signal timing performance with respect to the signal specifications, along with any decoded signal connotations. Graphical information can be overlaid onto the video with digital indications of the data or codewords presently in the signals shown by the video, while signal timing performance indicators might include color-coded or otherwise graduated/differentiated annotations which relate to how close the on-screen signals are to the one or more protocol-based signal timing parameters or requirements. Signal timing errors might be flagged to users on-screen during replay of the video. In this manner, users can efficiently capture video of a startup sequence or other time-based sequence of signaling presented on an oscilloscope and the user can later process the video for analysis via annotation system 130. A processed video might then be shared with one or more other users using a collaboration service or streaming video service to debug errors or failures in target circuit 111.

The signal specification discussed above might be employed to further aid an operator or user. For example, a user performing manufacturing, assembly, debug, testing, or repair processes might employ a user device to capture images or video of an oscilloscope screen displaying waveforms for a circuit under test. Annotations or overlays as discussed herein can be presented to the user, such as on an AR device, display screen, or smartphone, which indicates when signals are out of specification, such as by not meeting signal timing parameters, amplitude parameters, rise/fall parameters, noise thresholds, protocol timings, or other specifications as applied to signals. Various user interface elements might be presented to the user, such as color coded indications on the severity of the specification outage for the displayed signals. Annotation system 130 can determine probably causes of the signals being out of specification, such as the circuit having incorrect or faulty electrical components currently installed. For example, an incorrect resistor or capacitor component might be installed, or such component might have failed, and the circuit is presently undergoing repair. Annotation system 130 can generate overlays which annotate the signal with one or more indications of the out-of-specification condition related to the displayed signals. Timing specification can be loaded by annotation system 130 from one or more storage systems or databases which relate to the components under test.

Instructions can be indicated (215) on-screen to the user which indicates that one or more changes should be made to the circuit under test. These changes can comprise component changes, where the component might comprise electrical components, mechanical components, software comments, firmware components, or other components. For example, the component changes might include swapping out an electrical component, such as a resistor or capacitor, or making alterations or changes to a physical configuration comprising an electromagnetic seal or mechanical adjustment to a physical component. Instructions can be annotated on-screen which indicate where the component is located on the circuit board. When AR systems are employed, then a user might look at a circuit under test and be presented with overlays which illustrate to the user a location of the target component to be replaced or examined Once the user replaces or repairs the component, then the annotations might be updated to show if the signal is now in specification. A user might be prompted to capture further waveforms or traces of the probed electrical components using the oscilloscope. For example, an on-screen annotation or overlay might change from red color indicating a faulty component or out-of-specification signal to a green color indicating a repaired component or in-specification signal. In addition to electrical components, software or firmware changes might be prompted in a similar fashion. For example, a user might be prompted to upload different firmware to a circuit board component which alters a signal waveform. Similar annotations or overlays as discussed for physical component changes can be display with regard to signals being in or out of specification before and after changes to the firmware. Once the repairs or component changes have been made and the waveforms are returned to an in-specification condition, then the user can be prompted that the repair is complete.

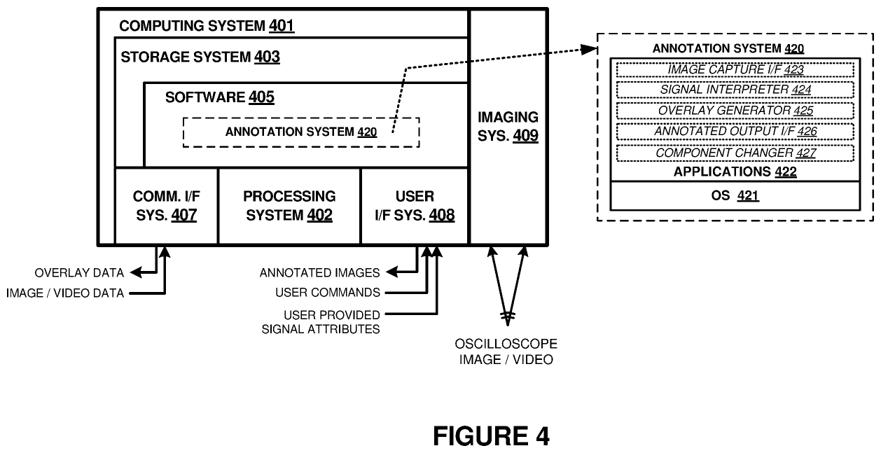

Returning to the elements of FIG. 1, signal annotation system 150 includes user device 120, annotation system 130, and display device 140. These elements of signal annotation system 150 might be included in combined equipment or devices, or may instead be included in one or more separate elements. Whether included in a single device or multiple devices, signal annotation system 150 comprises one or more computing systems or computing assemblies, such as a smartphone, tablet computing device, computer, laptop computer, gaming system, entertainment system, server, appliance, or other computing system, including combinations thereof. Portions of signal annotation system 150, such as annotation system 130, might comprise one or more distributed computing or cloud computing elements. In such instances, user device 120 can transfer image data or video data to annotation system 130 for remote cloud-based processing of the image/video data. Furthermore, signal annotation system 150 can include peripheral and assembly elements, namely enclosure elements, thermal management elements, memory elements, storage elements, communication interfaces, and graphics elements, among other elements. FIG. 4 details further implementation examples for signal annotation system 150.

Elements of signal annotation system 150, such as user device 120, annotation system 130, and display device 140, might comprise one or more microprocessors and other processing circuitry that retrieves and executes software, such as user interfaces, operating systems, and user applications from an associated storage system. An included data processor of signal annotation system 150 can comprise one or more integrated circuit elements, such as processor cores, graphics cores, cache memory, and communication interfaces, among other elements not shown for clarity. Signal annotation system 150 can be implemented within a single processing device but can also be distributed across multiple processing devices or sub-systems that cooperate in executing program instructions. Examples of data processors included in signal annotation system 150 include general purpose central processing units, application specific processors, and logic devices, as well as any other type of processing device, combinations, or variations thereof. In some examples, data processors included in signal annotation system 150 comprise an Intel® or AMD® microprocessor, ARM® microprocessor, field-programmable gate array (FPGA), application specific integrated circuit (ASIC), application specific processor, or other microprocessor or processing elements.

In some instances, user device 120 comprises a digital camera system or imaging system capable of capturing images or video for transfer and storage as digital files. Imaging device 121 might comprise a complementary MOS (CMOS) imaging sensor or charge-coupled device (CCD) imaging sensor that captures incident light, assisted by associated lenses, reflectors, illuminators, and similar equipment. These images are assembled into one or more files that may be discrete images, bundled images, or video files. Audio may also be captured in some examples. Display device 140 can comprise any suitable monitor, display screen, projector, television, and the like, which may include a touchscreen or other similar features. At least user device 120 and display device 140 might be integrated into a single user device, such as a smartphone, tablet device, personal computer, virtual reality user device, augmented reality user device, or other user device. Annotation system 130 can comprise a separate processing elements separate from the integrated user device, or may be integrated with user device 120 and display device 140 as well. Furthermore, portions of user device 120, annotation system 130, and display device 140 might be implemented with software, firmware, scripting, or other encoded instructions.

Links 160-161 can comprise various wired or wireless links or network links, such as Ethernet, Peripheral Component Interconnect Express (PCIe), Gen-Z, InfiniBand, FibreChannel, Thunderbolt, universal serial bus (USB), HyperTransport (HT), among others, including combinations thereof. Various communication protocols and communication signaling can be employed by links 160-161, which might include networking, transport, and link layers, such as Internet Protocol (IP) and Transmission Control Protocol (TCP). Custom, chip-level, or application-specific portions of links 160-161 can also be included.

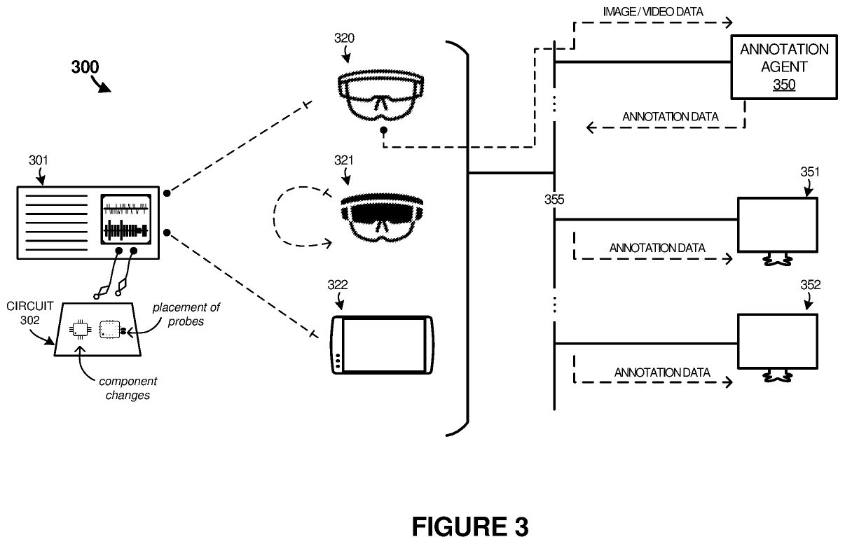

FIG. 3 illustrates signal analysis system 300 in an implementation. System 300 includes oscilloscope 301, test circuit 302, user devices 320-322, annotation agent 350, and user systems 351-352. User devices 320-322, annotation agent 350, and user systems 351-352 can communicate over one or more communication links, which in FIG. 3 is illustrated by exemplary communication network 355. Further communication links or networks might instead be employed. Although annotation agent 350 is shown as a separate element in FIG. 3, annotation agent 350, or portions thereof, might be included in any among user devices 320-322 or user systems 351-352.

Oscilloscope 301 comprises one or more pieces of laboratory or diagnostic equipment that allow a user or operator to monitor a test subject. This test subject might include target electrical circuitry, such as circuit boards, circuit traces, circuit components, and the like. Oscilloscope 301 includes one or more display screens for displaying signals or traces which represent activity of the test subject. These displayed signals comprise graphical representations of analog or digital signals of monitored test subjects. Although the example in FIG. 3 includes an oscilloscope, other electrical monitoring equipment might instead be employed, such as signal analyzers, spectrum analyzers, logic analyzers, bus analyzers, and the like. In further examples, oscilloscope 301 might instead comprise other monitoring or diagnostic equipment, such as medical monitoring equipment, industrial monitoring equipment, commercial production control equipment, and the like. However, the examples of various types of equipment typically have a display screen which displays signals or traces of monitored test subjects provided by one or more probe elements or sensor elements.

User devices 320-322 typically include general purpose processors, graphics processors, memory, network interfaces, and storage typical of computing devices. Moreover, user devices 320-322 each include digital cameras or imaging equipment, along with one or more display screens. User device 320 comprises an augmented reality (AR) user device, such as a Microsoft HoloLens®, which has a head-mounted display and imaging system incorporated therein. Typically, AR devices include a transparent or semi-transparent display which allows a user to view a real-world scene while also viewing projected graphics composited onto the real-world scene that appear included as a part of the scene. This can be accomplished using various projection or display technologies, along with human-machine interface equipment. User device 321 comprises a virtual reality (VR) user device, which has a head-mounted display and imaging system incorporated therein. Typically, VR devices include an opaque display which allows a user to view a computer-generated scene preventing the user from seeing real-world scenes through any associated goggles or display. Although VR systems can include images of the real-world scenes, these scenes are typically digital versions of the scenes. Added graphics or video can be included into the scene presented to the user. User device 322 comprises a smartphone or tablet computing device, although other similar devices are possible such as laptops, portable computers, gaming systems, or telecommunication hubs, among other devices.

Annotation agent 350 comprises one or more microprocessors and other processing circuitry that retrieves and executes software, such as user interfaces, operating systems, and user applications from an associated storage system. An included data processor of annotation agent 350 can comprise one or more integrated circuit elements, such as processor cores, graphics cores, cache memory, and communication interfaces, among other elements not shown for clarity. Annotation agent 350 can be implemented within a single processing device but can also be distributed across multiple processing devices or sub-systems that cooperate in executing program instructions. Examples of data processors included in annotation agent 350 include general purpose central processing units, application specific processors, and logic devices, as well as any other type of processing device, combinations, or variations thereof. Furthermore, annotation agent 350 might be implemented over one or more a distributed computing or cloud computing based systems, which may include various physical and virtualized computing and storage elements.

User systems 351-352 can comprise any suitable end user device, such as a smartphone, tablet computing device, computer, laptop computer, gaming system, entertainment system, server, appliance, or other computing system, including combinations thereof. In some examples, user systems 351-352 comprise virtualized computing devices, or may comprise graphical user interfaces provided for elements of annotation agent 350. These user interfaces or virtualized devices can include web interfaces, browser-based interfaces, cloud interfaces, console interfaces, and the like. In some examples, user systems 351-352 comprise end users or clients of a collaborative or cloud-based communication/conferencing system, such as Microsoft Skype®, Microsoft Teams®, or other similar system. User devices 320-322 might also be coupled into the collaborative environment provided by a similar communication/conferencing system, and act as end users or clients as well. When in a communication/conferencing system, one or more among user devices 320-322, user systems 351-352, and annotation agent 350 might have roles comprising client, server, consumer, host, leader, participant, or other roles which may change during communication exchange.

Network 355 includes one or more packet networks comprising local area networks (LANs) or wide area networks (WANs), which might feature intranets, internets, the Internet, virtual private networks (VPNs), and other network configurations. Network links among network 355 can comprise various optical, wired, wireless, or hybrid links or network links, such as Ethernet, Wi-Fi, digital cellular, satellite, Data Over Cable Service Interface Specification (DOCSIS), Digital subscriber line (DSL), or other similar links. Various protocols and signaling can be employed by network 355, which might include networking, transport, and link layers, such as Internet Protocol (IP) and Transmission Control Protocol (TCP).

In operation, annotation agent 350 obtains one or more digital images that capture a user interface of oscilloscope 301 presenting a trace of a signal monitored by oscilloscope 301. Oscilloscope 301 might include a display screen or other local or remote user interface which graphically displays one or more signal traces to a user. A user device that includes an imaging sensor, such as user devices 320-322, might capture an image or video of this display screen using the imaging sensor. Alternatively, a screen shot of the graphical elements of the display screen of oscilloscope 301 might be performed on oscilloscope 301, and such image data, image files, or video data can be transferred from oscilloscope 301 via network interface, communication interface, or removable storage drive. Annotation agent 350 might receive live or streaming video of the display screen of oscilloscope 301, such as via an imaging sensor of user devices 320-322. Annotation agent 350 might receive a file or other data set previously captured of display screen of oscilloscope 301.

Annotation agent 350 then processes at least the one or more digital images to identify one or more traces representing associated signals. These traces might be identified among the graphical data comprising the one or more digital images. In some examples, the traces might be identified by position within the image or video with respect to a display screen or within selected graphical user interface elements, may be identified using various image or object recognition processes, or may instead be identified using various machine learning or artificial intelligence operations, including combinations thereof.

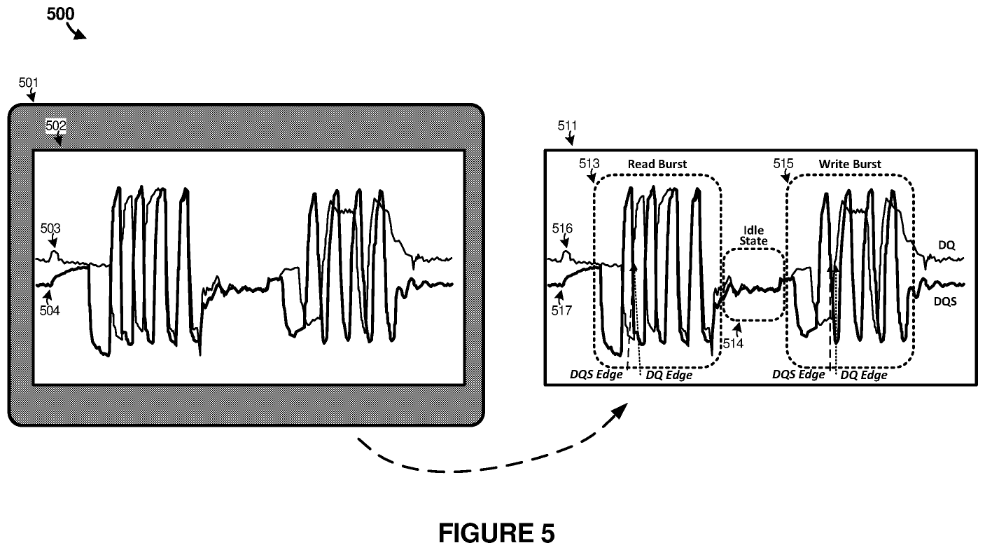

Once the traces are identified, annotation agent 350 decodes a connotation of the signal. FIGS. 5-7 illustrate example connotations. A signal connotation comprises the information carried by the signal, which might include a digital bit or bits, digital codeword, transaction or packet type, frame boundaries, transmission-level or link-level properties of a carried protocol, or other information. In one example, the signal connotation comprises a digital value carried by the signal which represents bits carried or encoded into the signal or a portion of a signal indicated in the trace. Various signal levels determined for the trace can be used to determine values carried by the signal, such as ‘high’ or ‘low’ signal levels, whether relative to each other or absolute with regard to predetermined voltage levels or amplitudes. The signals may be encoded versions of bits or codewords, and annotation agent 350 can decode the encoded signals to determine the signal connotation. Annotation agent 350 might process at least the trace in the one or more digital images to determine a clock signal indicated by the trace, and process a different trace in the one or more digital images to determine a data signal. Annotation agent 350 might interpret at least a portion of the data signal using the clock signal to decode the connotation of the data signal. In some cases, the clock signal is embedded in the data signal, and thus annotation agent 350 might decode the signal to determine both the clock and the connotation of the data signal from the same trace. In yet further examples, annotation agent 350 might receive one or more user indications of attributes associated with the signal monitored by oscilloscope 301. The attributes can comprise a protocol type associated with the signal, a signal amplitude property, and a signal time scale property, or other user-provided information which provides context to the trace or signal. Annotation agent 350 can then process the trace along with one or more of the attributes to decode the connotation of the signal. For example, a user might indicate that the protocol comprises I2C, and then annotation agent 350 can use this attribute to better or more quickly identify a digital codeword carried by the signal of the trace. Annotation agent 350 might include a user interface to accept user input, or can accept various text files, configuration files, or other input styles.

In another example, a user might operate one of user devices 320-322 to capture an operational sequence for a selected bus or set of signals of test circuit 302, as shown over time on a display screen of oscilloscope 301. The user device can capture a video or sequence of images over a selected timeframe to capture a sequence of signals shown on a display screen of oscilloscope 301. For instance, the user device might record a trace of a bus shown on oscilloscope 301 from boot of a processor to boot failure or boot completion, and then annotation agent 350 can process this recorded trace to output a running translation of what occurred on that bus. The running translation could be used to troubleshoot hanging systems or to verify proper serial data was transferred over the bus, among other troubleshooting activities. Glitch detection or signal timing analysis can be performed, such as detecting and annotating when monitored signals fall outside of acceptable or decodable bounds, or annotating instances that a monitored circuit component fails to send what is appropriate for a protocol or fails in an intended operation. Signal integrity can also be monitored and detected in recoded video or image sequences, and a user can be alerted via annotation agent 350. For example, noise present on a bus might sometimes manifest as a change to the data bit from a 0 to 1, or vice versa. Annotation agent 350 can detect and flag via annotations such instances or deviations from expected signal norms. Rise times, fall times, eye diagram analyses, signal levels, signal anomalies, excessive noise, interference, and other signal occurrences can be detected in video or images and be annotation to a user for replay or viewing of the video/images.

Once the connotations and signal timing analyses of the signals have been determined, then annotation agent 350, based at least on the connotations and analyses, generates an annotation or overlay indicating one or more characteristics of the signals. The annotations can comprise an overlay which is combined with the original digital images received. This overlay might include text labels or graphical labels which indicate the connotation of the signals, such as digital values carried by signals or waveforms, transaction phases, protocol information, clock rates, amplitudes or voltage levels, frame boundaries, transaction types, signal timing performance, signal integrity status, or other information which a user can employ to interpret the waveforms of the signals. Various font or typeface selections can be made, along with colors, sizing, and contrast of annotations or overlays. These selections might be automated by annotation system 350, or may be user configurable.

In one example, such as when a user device captures the image or video of the display screen of oscilloscope 301, then that same user device might display at least one digital image of the oscilloscope display or oscilloscope user interface with the annotation overlay on a display of the user device. This might comprise a ‘live’ view of the oscilloscope screen with annotations composited into a live view of the oscilloscope screen. In another example, a user device or user system might the one or more digital images composited with the annotation overlay on the display of the user device during capture of at least one digital image of the oscilloscope user interface. In another example, the image data might be captured prior to annotation, and stored for later use in a storage system. This image data can be later post-processed by annotation agent 350 to provide for the annotations or overlays. In yet another example, the one or more digital images comprise a digital video captured of the oscilloscope user interface. Based at least on the connotations changing over time for the signal in the digital video, then annotation agent 350 can update the annotations or overlays according to changes in the connotations. A user device or user system might display the digital video composited with the annotation overlay updated according to the changes in the connotation.

In another example, annotation agent 350 can be configured to process a trace in one or more digital images captured of the display screen of oscilloscope 301 to determine one or more timing properties of a signal indicated by the trace. The one or more timing properties can be determined based at least on the one or more timing properties of the signal with respect to signal specifications or signal performance targets. Annotation agent 350 can then be configured to generate one or more overlays that indicate performance of the signal with respect to the signal specification. When the signal performance does not meet the signal specification, then annotation agent 350 can indicate one or more component changes to a circuit associated with the signal to alter the signal performance. The component changes might comprise electrical components or software/firmware components, among other components. Annotation agent 350 can be configured to analyze further images captured of oscilloscope 301 to determine when the component changes bring the signal performance back into alignment with the signal specification, and indicate annotations to the user indicating such result.

FIG. 5 illustrates example 500 of an annotation overlay in an implementation. In FIG. 5, oscilloscope display screen 501 includes trace portion 502 that includes two traces 503 and 504. A user device, such as any among user devices 320-322 of FIG. 3 might capture a digital image or digital video of display screen 501 or trace portion 502. Annotation agent 350 can receive this digital image or digital video and process as noted herein to determine connotations of signals indicated in traces 503 and 504. One or more overlays or annotations can be generated based on the connotations, and these can be composited onto the digital image or digital video for display to a user. Graphical image 511 is presented in FIG. 5 to illustrate one example annotation. In image 511, various annotations are included that provide information related to traces 503-504, now shown as waveforms 516-517. In particular, transaction types and signal states are annotated as overlays, namely read burst transaction 513, idle state 514, and write burst 515. Other information is shown, such as a signal label for each waveform, namely DQ and DQS, and edge detection for certain portions of the waveforms, namely DQ edge and DQS edge.

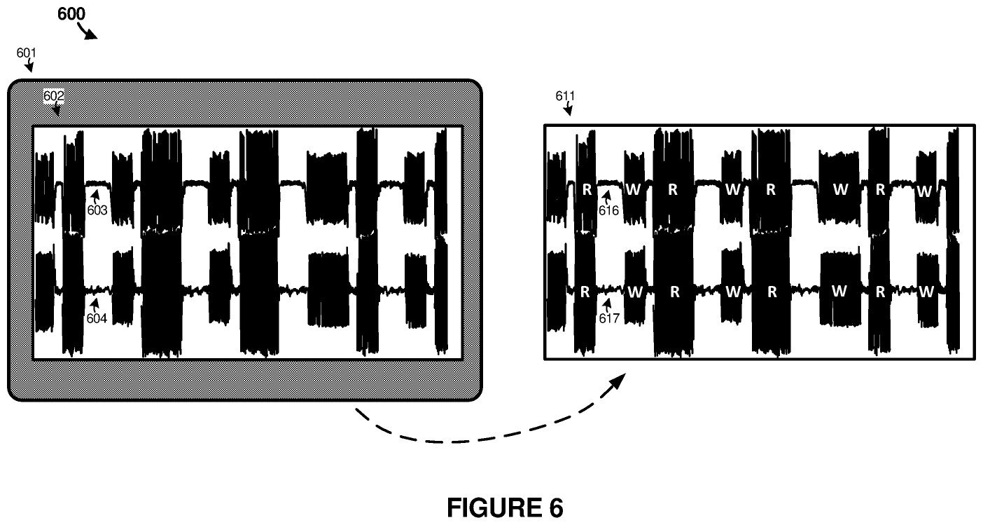

FIG. 6 illustrates example 600 of an annotation overlay in an implementation. In FIG. 6, oscilloscope display screen 601 includes trace portion 602 that includes two traces 603 and 604. A user device, such as any among user devices 320-322 of FIG. 3 might capture a digital image or digital video of display screen 601 or trace portion 602. Annotation agent 350 can receive this digital image or digital video and process as noted herein to determine connotations of signals indicated in traces 603 and 604. One or more overlays or annotations can be generated based on the connotations, and these can be composited onto the digital image or digital video for display to a user. Graphical image 611 is presented in FIG. 6 to illustrate one example annotation. In image 611, various annotations are included that provide information related to traces 603-604, now shown as waveforms 616-617. In particular, transaction types are annotated as overlays, namely read (R) and write (W) transaction types.

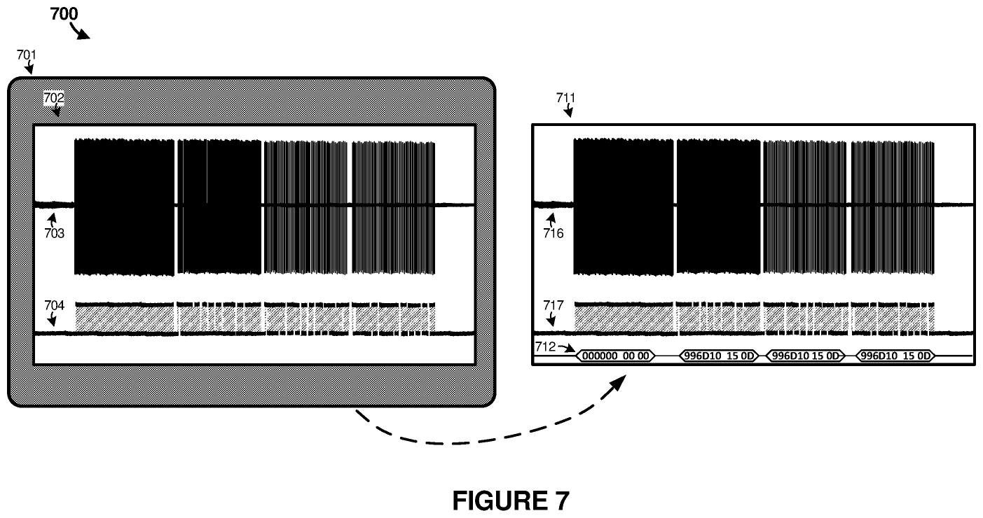

FIG. 7 illustrates example 700 of an annotation overlay in an implementation. In FIG. 7, oscilloscope display screen 701 includes trace portion 702 that includes two traces 703 and 704. A user device, such as any among user devices 320-322 of FIG. 3 might capture a digital image or digital video of display screen 701 or trace portion 702. Annotation agent 350 can receive this digital image or digital video and process as noted herein to determine connotations of signals indicated in traces 703 and 704. One or more overlays or annotations can be generated based on the connotations, and these can be composited onto the digital image or digital video for display to a user. Graphical image 711 is presented in FIG. 7 to illustrate one example annotation. In image 711, various annotations are included that provide information related to traces 703-704, now shown as waveforms 716-717. In particular, decoded digital codewords 712 are shown transposed below the waveforms. These digital codewords comprise decoded digital bits carried by the signals shown in the waveforms. The digital codewords can be determined based on both signals in image 711, where a first waveform might comprise a clock signal and a second signal waveform might comprise a data signal. The data signal can be interpreted in light of the clock signal, and the data signal can be decoded to determine the digital codewords shown.

FIG. 4 illustrates a computing system configured to implement at least a portion of a signal analysis system in an implementation. FIG. 4 illustrates computing system 401 that is representative of any system or collection of systems in which the various operational architectures, scenarios, and processes disclosed herein may be implemented. For example, computing system 401 can be used to implement elements of signal annotation system 150 of FIG. 1, or elements of annotation agent 350 or user devices 320-322 of FIG. 3.

Examples of user devices 120, display device 140, user devices 320-322, or user systems 351-352 when implemented by computing system 401 include, but are not limited to, a smartphone, tablet computer, laptop, personal communication device, personal assistance device, wireless communication device, subscriber equipment, customer equipment, access terminal, telephone, mobile wireless telephone, personal digital assistant, personal computer, e-book, mobile Internet appliance, wireless network interface card, media player, game console, gaming system, or some other communication apparatus, including combinations thereof. Examples of annotation system 130 or annotation agent 350 when implemented by computing system 401 include, but are not limited to, user devices, server computers, cloud computing systems, distributed computing systems, software-defined networking systems, computers, desktop computers, hybrid computers, rack servers, web servers, cloud computing platforms, and data center equipment, as well as any other type of physical or virtual server machine, and other computing systems and devices, as well as any variation or combination thereof.

Computing system 401 may be implemented as a single apparatus, system, or device or may be implemented in a distributed manner as multiple apparatuses, systems, or devices. Computing system 401 includes, but is not limited to, processing system 402, storage system 403, software 405, communication interface system 407, and user interface system 408. Processing system 402 is operatively coupled with storage system 403, communication interface system 407, and user interface system 408. When implementing a user device, computing system 401 can also include imaging system 409.

Processing system 402 loads and executes software 405 from storage system 403. Software 405 includes annotation system 420, which is representative of the processes, services, and platforms discussed with respect to the included Figures. When executed by processing system 402 to provide oscilloscope user interface capture, image transfer, signal interpretation, overlay generation, or annotation output, among other services, software 405 directs processing system 402 to operate as described herein for at least the various processes, operational scenarios, and sequences discussed in the foregoing implementations. Computing system 401 may optionally include additional devices, features, or functionality not discussed for purposes of brevity.

Referring still to FIG. 4, processing system 402 may comprise a micro-processor and processing circuitry that retrieves and executes software 405 from storage system 403. Processing system 402 may be implemented within a single processing device, but may also be distributed across multiple processing devices or sub-systems that cooperate in executing program instructions. Examples of processing system 402 include general purpose central processing units, application specific processors, and logic devices, as well as any other type of processing device, combinations, or variations thereof.

Storage system 403 may comprise any computer readable storage media readable by processing system 402 and capable of storing software 405. Storage system 403 may include volatile and nonvolatile, removable and non-removable media implemented in any method or technology for storage of information, such as computer readable instructions, data structures, program modules, or other data. Examples of storage media include random access memory, read only memory, magnetic disks, optical disks, flash memory, virtual memory and non-virtual memory, magnetic cassettes, magnetic tape, magnetic disk storage or other magnetic storage devices, or any other suitable storage media. In no case is the computer readable storage media a propagated signal.

In addition to computer readable storage media, in some implementations storage system 403 may also include computer readable communication media over which at least some of software 405 may be communicated internally or externally. Storage system 403 may be implemented as a single storage device, but may also be implemented across multiple storage devices or sub-systems co-located or distributed relative to each other. Storage system 403 may comprise additional elements, such as a controller, capable of communicating with processing system 402 or possibly other systems.

Software 405 may be implemented in program instructions and among other functions may, when executed by processing system 402, direct processing system 402 to operate as described with respect to the various operational scenarios, sequences, and processes illustrated herein. For example, software 405 may include program instructions for implementing oscilloscope user interface capture, image transfer, signal interpretation, overlay generation, or annotation output, among other services.

In particular, the program instructions may include various components or modules that cooperate or otherwise interact to carry out the various processes and operational scenarios described herein. The various components or modules may be embodied in compiled or interpreted instructions, or in some other variation or combination of instructions. The various components or modules may be executed in a synchronous or asynchronous manner, serially or in parallel, in a single threaded environment or multi-threaded, or in accordance with any other suitable execution paradigm, variation, or combination thereof. Software 405 may include additional processes, programs, or components, such as operating system software or other application software, in addition to or that include annotation system 420. Software 405 may also comprise firmware or some other form of machine-readable processing instructions executable by processing system 402.

In general, software 405 may, when loaded into processing system 402 and executed, transform a suitable apparatus, system, or device (of which computing system 401 is representative) overall from a general-purpose computing system into a special-purpose computing system customized to provide imaging assistance services, document recognition services, or scene description services, among other assistance services. Indeed, encoding software 405 on storage system 403 may transform the physical structure of storage system 403. The specific transformation of the physical structure may depend on various factors in different implementations of this description. Examples of such factors may include, but are not limited to, the technology used to implement the storage media of storage system 403 and whether the computer-storage media are characterized as primary or secondary storage, as well as other factors.

For example, if the computer readable storage media are implemented as semiconductor-based memory, software 405 may transform the physical state of the semiconductor memory when the program instructions are encoded therein, such as by transforming the state of transistors, capacitors, or other discrete circuit elements constituting the semiconductor memory. A similar transformation may occur with respect to magnetic or optical media. Other transformations of physical media are possible without departing from the scope of the present description, with the foregoing examples provided only to facilitate the present discussion.

Annotation system 420 includes one or more software elements, such as OS 421 and applications 422. Applications 422 can include image capture interface 423, signal interpreter 424, signal interpreter 424, and annotated output interface 426. Image capture interface 423 captures image data via imaging system 409 or receives image data over communication interface 407. This image data can include static images, digital photos, video data, audio data, and other metadata that supports such data. When image capture interface 423 receives this image data over communication interface 407, the image data might comprise one or more data files or streaming data that might be compressed, encrypted, or encoded. When image capture interface 423 captures image data local to computing system 401, then image capture interface 423 can operate imaging system 409 to capture image data local to computing system 401, such as oscilloscope display screens or other real-world scenes.

Signal interpreter 424 process image data from one or more image or video files and interprets traces contained in those image or video files to determine connotations of the signals. Signal interpreter 424 can receive user commands on the captured images, such as contextual information, attributes, or other user-provided signal properties. However, signal interpreter 424 interprets the actual waveforms included in the image data. Signal interpreter 424 can employ local processing elements or one or more remote platforms or services deployed over a distributed computing system that are interfaced via communication interface 407. Overlay generator 425 generates graphics to describe signal traces based on results of signal interpreter 424. These graphics might comprise various combined/composed overlays that form annotations for the waveforms. Other annotation types might be included, such as audio annotations, computer-generated voice annotations, tones, audio indicators/alerts, or other types of annotations based on the results of signal interpreter 424. Annotated output interface 426 transfers the annotations or graphical overlays over communication interface 407 or for display via user interface system 408. The annotations or overlays might comprise one or more images, markup, text files, video data or other information that can be combined with the original image data to form annotated views of the captured oscilloscope screens. These annotated views can be displayed via graphical user interfaces of user interface system 408, or might instead be hosted or transferred to a remote system over communication interface system 470, such as over a virtualized display or web interface.

Component changer 427 processes signal traces or waveforms indicated within imaging data to determine when signals do not meet a signal specification or signal target performance. Component changer 427 can determine one or more component changes which might alter performance of the signal and bring the signal into alignment with the specification or target performance Component changer 427 might determine the component is a physical component or a software/firmware component. Component changer 427 can indicate to a user on-screen prompts or overlays which instruct the user on the component to be changed. Component changer 427 can analyze subsequent signal waveforms or traces captured to determine if the component change brought the signal back into alignment with the specification, or suggest further component changes.

Communication interface system 407 may include communication connections and devices that allow for communication with other computing systems (not shown) over communication networks (not shown). Examples of connections and devices that together allow for inter-system communication may include network interface cards, antennas, power amplifiers, RF circuitry, transceivers, and other communication circuitry. The connections and devices may communicate over communication media to exchange communications with other computing systems or networks of systems, such as metal, glass, air, or any other suitable communication media. Physical or logical elements of communication interface system 407 can receive link/quality metrics, and provide link/quality alerts or dashboard outputs to users or other operators.

Communication between computing system 401 and other computing systems (not shown), may occur over a communication network or networks and in accordance with various communication protocols, combinations of protocols, or variations thereof. For example, computing system 401 when implementing a user device, might communicate with another user device or annotation system/service. Examples networks include intranets, internets, the Internet, local area networks, wide area networks, wireless networks, wired networks, virtual networks, software defined networks, data center buses, computing backplanes, or any other type of network, combination of network, or variation thereof. The aforementioned communication networks and protocols are well known and need not be discussed at length here. However, some communication protocols that may be used include, but are not limited to, the Internet protocol (IP, IPv4, IPv6, etc. . . . ), the transmission control protocol (TCP), and the user datagram protocol (UDP), as well as any other suitable communication protocol, variation, or combination thereof.

User interface system 408 may include a keyboard, a mouse, a voice input device, a touch input device for receiving input from a user. Output devices such as a display, speakers, web interfaces, terminal interfaces, and other types of output devices may also be included in user interface system 408. User interface system 408 can provide output and receive input over a network interface, such as communication interface system 407. In network examples, user interface system 408 might packetize display or graphics data for remote display by a display system or computing system coupled over one or more network interfaces. User interface system 408 may comprise application programming interface (API) elements for interfacing with users, other data systems, other user devices, web interfaces, and the like. User interface system 408 may also include associated user interface software executable by processing system 402 in support of the various user input and output devices discussed above. Separately or in conjunction with each other and other hardware and software elements, the user interface software and user interface devices may support a console user interface, graphical user interface, a natural user interface, or any other type of user interface.

Imaging system 409 comprises various hardware and software elements for capturing digital images, video data, audio data, or other sensor data which can be used to capture signal traces rendered by one or more oscilloscope devices or other signal capture devices. Imaging system 409 can include digital imaging elements, digital camera equipment and circuitry, microphones, light metering equipment, illumination elements, or other equipment and circuitry. Analog-to-digital conversion equipment, filtering circuitry, image or audio processing elements, or other equipment can be included in imaging system 409.

Certain inventive aspects may be appreciated from the foregoing disclosure, of which the following are various examples.

Example 1: A method, comprising obtaining one or more digital images that capture an oscilloscope user interface presenting a trace of a signal monitored by the oscilloscope, processing at least the trace in the one or more digital images to decode a connotation of the signal, and based at least on the connotation, generating an annotation overlay indicating one or more characteristics of the signal.

Example 2: The method of Example 1, where obtaining the one or more digital images comprises capturing the one or more digital images on a user device comprising an imaging sensor; and further comprising displaying at least one digital image of the oscilloscope user interface with the annotation overlay on a display of the user device.

Example 3: The method of Examples 1-2, further comprising displaying the one or more digital images composited with the annotation overlay on the display of the user device during capture of at least one digital image of the oscilloscope user interface, where the user device comprises at least one among a smartphone device, tablet computing device, virtual reality device, and augmented reality device.

Example 4: The method of Examples 1-3, where obtaining the one or more digital images comprises receiving the one or more digital images over a network interface of a first user device, where the one or more digital images were captured by a second user device comprising an imaging sensor, and further comprising displaying at least one digital image captured of the oscilloscope user interface with the annotation overlay on a display of the first user device.

Example 5: The method of Examples 1-4, where the one or more digital images comprise a digital video captured of the oscilloscope user interface, and further comprising based at least on the connotation changing over time for the signal, updating the annotation overlay according to changes in the connotation.

Example 6: The method of Examples 1-5, further comprising processing at least the trace in the one or more digital images to determine one or more timing properties of the signal, and based at least on the one or more timing properties, generating an additional annotation overlay indicating one or more additional characteristics of the signal.

Example 7: The method of Examples 1-6, further comprising based at least on the one or more timing properties of the signal, indicating performance of the signal with respect to a signal specification, and indicating one or more component changes to a circuit associated with the signal to alter the performance.

Example 8: The method of Examples 1-7, further comprising receiving one or more user indications of attributes associated with the signal monitored by the oscilloscope, where the attributes comprise one or more among a protocol type associated with the signal, a signal amplitude property, and a signal time scale property, and processing the trace along with one or more of the attributes to decode the connotation of the signal.

Example 9: The method of Examples 1-8, where the annotation overlay comprises indications of at least one among a digital codeword carried by the signal and a transaction type indicated by the signal.

Example 10: The method of Examples 1-9, further comprising receiving identifiers of the signal and a target circuit associated with the signal, and based on the identifiers, determining locations on the target circuit for placement of probes of the oscilloscope to monitor the signal. The method also includes displaying the locations to a user in an augmented reality view of the circuit.

Example 11: A signal annotation system, comprising an image interface configured to obtain one or more digital images that capture an oscilloscope user interface presenting a trace of a signal monitored by the oscilloscope, a signal interpreter configured to process at least the trace in the one or more digital images to decode a connotation of the signal, and an overlay generator configured to generate an annotation overlay indicating one or more characteristics of the signal based at least on the connotation.

Example 12: The signal annotation system of Example 11, comprising an imaging sensor configured to capture the one or more digital images, and a user interface configured to present at least one digital image of the oscilloscope user interface with the annotation overlay, and present the one or more digital images composited with the annotation overlay during capture of at least one digital image of the oscilloscope user interface.

Example 13: The signal annotation system of Examples 11-12, comprising a network interface configured to receive the one or more digital images, where the one or more digital images were captured by a user device comprising an imaging sensor, and a user interface configured to present at least one digital image captured of the oscilloscope user interface with the annotation overlay.

Example 14: The signal annotation system of Examples 11-13, where the one or more digital images comprise a digital video captured of the oscilloscope user interface, and comprising the signal interpreter configured to determine a changing connotation over time for the signal, the overlay generator configured to update the annotation overlay according to the changing connotation, and a user interface configured to display the digital video composited with the annotation overlay updated according to the changing connotation.

Example 15: The signal annotation system of Examples 11-14, comprising a user interface configured to receive one or more user indications of attributes associated with the signal monitored by the oscilloscope, where the attributes comprise one or more among a protocol type associated with the signal, a signal amplitude property, and a signal time scale property, and the signal interpreter configured to process the trace along with one or more of the attributes to decode the connotation of the signal.

Example 16: The signal annotation system of Examples 11-15, where the annotation overlay comprises indications of at least one among a digital codeword carried by the signal and a transaction type indicated by the signal.

Example 17: The signal annotation system of Examples 11-16, comprising the signal interpreter configured to receive identifiers of the signal and a target circuit associated with the signal, and based on the identifiers, determine physical locations on the target circuit for placement of probes of the oscilloscope to monitor the signal. The overlay generator is configured to display the locations to a user in an augmented reality view of the circuit.

Example 18: The signal annotation system of Examples 11-17, the signal interpreter configured to process at least the trace in the one or more digital images to determine one or more timing properties of the signal. Based at least on the one or more timing properties of the signal, the overlay generator is configured to indicate performance of the signal with respect to a signal specification, and the overlay generator configured to indicating one or more component changes to a circuit associated with the signal to alter the performance.

Example 19: An apparatus, comprising one or more computer readable storage media, a processing system operatively coupled with the one or more computer readable storage media, and program instructions stored on the one or more computer readable storage media. Based on being read and executed by the processing system, the program instructions direct the processing system to at least obtain one or more digital images that capture an oscilloscope user interface presenting a trace of a signal monitored by the oscilloscope process at least the trace in the one or more digital images to decode a connotation of the signal comprising at least one among a digital codeword carried by the signal and a transaction type indicated by the signal, and generate an annotation overlay indicating one or more characteristics of the signal based at least on the connotation.

Example 20: The apparatus of Example 19, comprising further program instructions. Based on being executed by the processing system, the further program instructions direct the processing system to at least process at least the trace in the one or more digital images to determine one or more timing properties of the signal, and based at least on the one or more timing properties, generate an additional annotation overlay indicating one or more additional characteristics of the signal.

The functional block diagrams, operational scenarios and sequences, and flow diagrams provided in the Figures are representative of exemplary systems, environments, and methodologies for performing novel aspects of the disclosure. The descriptions and figures included herein depict specific implementations to teach those skilled in the art how to make and use the best option. For the purpose of teaching inventive principles, some conventional aspects have been simplified or omitted. Those skilled in the art will appreciate variations from these implementations that fall within the scope of the invention. Those skilled in the art will also appreciate that the features described above can be combined in various ways to form multiple implementations. As a result, the invention is not limited to the specific implementations described above, but only by the claims and their equivalents.

1. A method, comprising:
obtaining a file comprising at least a digital image captured of an oscilloscope user interface while rendering a trace of a signal monitored by the oscilloscope;
performing image recognition on at least the digital image to identify properties of the trace;
based on the properties of the trace, decoding a connotation of the signal represented by the trace; and
generating an annotation overlay that presents an indication of the connotation concurrent with presentation of at least the digital image on a display.

2. The method of claim 1, wherein obtaining the file comprises capturing the digital image on a user device separate from the oscilloscope and comprising an imaging sensor; and further comprising:
displaying the digital image captured of the oscilloscope user interface with the annotation overlay on the display of comprising the user device.

3. The method of claim 2, further comprising:
displaying the annotation overlay composited on the display of the user device during capture of the oscilloscope user interface, wherein the user device comprises at least one among a smartphone device, tablet computing device, virtual reality device, and augmented reality device.

4. The method of claim 1, wherein obtaining the digital image comprises receiving the digital image over a network interface of a first user device;
wherein the digital image is captured by a second user device separate from the oscilloscope and comprising an imaging sensor; and further comprising:
displaying the digital image captured of the oscilloscope user interface with the annotation overlay on the display comprising the first user device.

5. The method of claim 1, wherein the digital image is a part of a digital video captured of the oscilloscope user interface, and further comprising:
based at least on the connotation changing over time for the signal, updating the annotation overlay according to changes in the connotation.

6. The method of claim 1, further comprising:
processing at least the trace in the digital image to determine one or more timing properties of the signal; and
based at least on the one or more timing properties, generating an additional annotation overlay indicating one or more additional characteristics of the signal.

7. The method of claim 6, further comprising:
based at least on the one or more timing properties of the signal, indicating performance of the signal with respect to a signal specification; and
indicating, on the display, one or more component changes to a circuit associated with the signal to alter the performance.

8. The method of claim 1, further comprising:
receiving one or more user indications of attributes associated with the signal monitored by the oscilloscope, wherein the attributes comprise one or more among a protocol type associated with the signal, a signal amplitude property, and a signal time scale property; and
processing the trace along with one or more of the attributes to decode the connotation of the signal comprising decoded data carried by the signal.

9. The method of claim 1, wherein the annotation overlay comprises decoded indications composited with the digital image on the display comprising at least one among a digital codeword carried by the signal and a transaction type indicated by the signal.

10. The method of claim 1, further comprising:
receiving identifiers of the signal and a target circuit associated with the signal;
based on the identifiers, determining locations on the target circuit for placement of probes of the oscilloscope to monitor the signal; and
displaying the locations to a user in an augmented reality view of the circuit shown on the display.

11. A signal annotation system, comprising:
an image interface configured to obtain a file comprising at least a digital image captured of an oscilloscope user interface while rendering a trace of a signal monitored by the oscilloscope;
a signal interpreter configured to perform image recognition on at least the digital image to identify properties of the trace, and based on the properties of the trace, decode a connotation of the signal represented by the trace; and
an overlay generator configured to generate an annotation overlay for a display that presents an indication of the connotation concurrent with presentation of at least the digital image.

12. The signal annotation system of claim 11, comprising:
an imaging sensor separate from the oscilloscope configured to capture the digital image; and
a user interface configured to present the annotation overlay composited during capture of the oscilloscope user interface.

13. The signal annotation system of claim 11, comprising:
a network interface configured to receive the digital image, wherein the digital image is captured by a user device separate from the oscilloscope and comprising an imaging sensor; and
a user interface configured to present the digital image captured of the oscilloscope user interface composited with the annotation overlay.

14. The signal annotation system of claim 11, wherein the digital image is a part of a digital video captured of the oscilloscope user interface, and comprising:
the signal interpreter configured to determine a changing connotation over time for the signal;
the overlay generator configured to update the annotation overlay according to the changing connotation; and
a user interface configured to display the digital video composited with the annotation overlay updated according to the changing connotation.

15. The signal annotation system of claim 11, comprising:
a user interface configured to receive one or more user indications of attributes associated with the signal monitored by the oscilloscope, wherein the attributes comprise one or more among a protocol type associated with the signal, a signal amplitude property, and a signal time scale property; and
the signal interpreter configured to process the trace along with one or more of the attributes to decode the connotation of the signal comprising decoded data carried by the signal.

16. The signal annotation system of claim 11, wherein the annotation overlay comprises decoded indications composited with the digital image on the display comprising at least one among a digital codeword carried by the signal and a transaction type indicated by the signal.

17. The signal annotation system of claim 11, comprising:
the signal interpreter configured to receive identifiers of the signal and a target circuit associated with the signal, and based on the identifiers, determine physical locations on the target circuit for placement of probes of the oscilloscope to monitor the signal; and
the overlay generator configured to display the locations to a user in an augmented reality view of the circuit shown the display.

18. The signal annotation system of claim 11, comprising:
the signal interpreter configured to process at least the trace in the digital image to determine one or more timing properties of the signal;
based at least on the one or more timing properties of the signal, the overlay generator configured to indicate performance of the signal with respect to a signal specification; and
the overlay generator configured to indicating, on the display, one or more component changes to a circuit associated with the signal to alter the performance.

19. An apparatus, comprising:
one or more computer readable storage media;
a processing system operatively coupled with the one or more computer readable storage media; and
program instructions stored on the one or more computer readable storage media that, based on being read and executed by the processing system, direct the processing system to at least:
obtain a file comprising at least a digital image captured of an oscilloscope user interface while rendering a trace of a signal monitored by the oscilloscope;
perform image recognition on at least the digital image to identify properties of the trace;
based on the properties of the trace, decode a connotation of the signal represented by the trace, the connotation comprising at least one among a digital codeword carried by the signal and a transaction type indicated by the signal; and
generate an annotation overlay for a display that presents an indication of the connotation concurrent with presentation of at least the digital image.

20. The apparatus of claim 19, comprising further program instructions, based on being executed by the processing system, direct the processing system to at least:
process at least the trace in the digital image to determine one or more timing properties of the signal; and
based at least on the one or more timing properties, generate an additional annotation overlay indicating one or more additional characteristics of the signal.
